(19) United States
(12) Patent Application Publication
(10) Pub. No.: US 2006/0181203 A1
(43) Pub. Date: Aug. 17, 2006

(54) Voltage-tuning multi-layer full-color conjugated polymer LED

(76) Inventors: Hsin-Fei Meng, Hsinchu (TW); Chang-Chih Huang, Yong-an Township (TW); Sheng-Fu Horng, Hsinchu (TW); Chain-Shu Hsu, Hsinchu (TW); Chia-Hsun Chen, Sansia Township (TW); Shinn-Rong Tzeng, Hsinchu (TW)

Correspondence Address: BUCKNAM AND ARCHER, 1077 NORTHERN BOULEVARD, ROSLYN, NY, 11576, US

(21) Appl. No.: 11/058,978

(22) Filed: Feb. 16, 2005

(51) Int. Cl. H01L 51/50; H05B 33/12

(52) U.S. Cl. 313/506; 428/690; 428/917; 313/504; 427/66; 257/103; 257/E51.022; 257/E51.027

(57) ABSTRACT

This invention relates to a device which is multilayer LEDs based on the commonly used high-efficiency electroluminescent conjugated polymers and can emitte the whole spectrum by varying voltage; wherein the structure of the device comprises a transparent electrode (TE) or a hole injection layer (HIL), several organic layers and an uppermost electron injection layer (EIL), characterized in choosing material of conjugated polymers with proper electron affinity (EA) and ionization potential (IP) for the organic layers.

### FIELD OF THE INVENTION

This invention relates to a LED device having conjugated polymers for emitting various colors of light in particular to a full-color range of light, and method for controlling the color by voltage-tuning multi-layer.

### DESCRIPTION OF THE PRIOR ART

Liquid crystal had been widely used in the field of computers, cellar phones and flat televisions, but still limited hereof due to its complicated process of manufacture, high processing cost and some disadvantages in many fields including view angle, brightness, color saturation and responding time. Comparatively, organic polymer as material of LEDs does not have such problems, especially the organic polymer can dissolve in solvent and the spin-coating process can be taken place, however, there also exist some practical problems to apply organic polymers in ink-jet techniques. Thus, in order to overcome such technical difficulties of organic compounds, conjugated polymers have been used as the emissive materials for efficient light-emitting diodes (LED).

The emission color is fixed by the band gap of particular conjugated polymers, such as Poly (p-phenylene vinylene) (PPF) and polyfluorene (PF) are the most two important families of conjugated polymers used in LED. PPF derivatives cover the red to green spectral range, while PF derivatives cover the whole visible range. It will be highly desirable if one single LED can emit light with a wide range of color, continuously turned by the applied voltage.

Such tunable LED can be applied in the whole color display, signaling, and illumination. There is currently a tremendous amount of effort on the PPV and PF display. In order to achieve a full color pixel, ink-jet and other techniques are being developed to deposit accurately three different kinds of polymers for red, green and blue in small areas. In addition to technical difficulties, such approaches sacrifice one great advantage of the conjugated polymers, namely, ease of direct spin coating to form large-area uniform films. It will be much simpler if the polymer film is uniformly formed while the color of each pixel is controlled by the voltage.

Accordingly, there are several literatures of organic color-tunable LED involving, for examples, the paper of M. Hamaguchi and K. Yoshino, ‘Color-variable emission in multilayer polymer electroluminescent devices containing electron-blocking layer’ (Jpn. J. Appl. Phys., 35, 4813(1996)), the paper of Y. Z. Wang, R. G. Sun, D. K. Wang, T. M. Swager and A. J. Epstein (Appl. Phys. Lett., 74, 2593(1999)) and the paper of S. Welter, K. Brunner, J. W. Hofstraat & L. De Cola, ‘Electroluminescent device with reversible switching between red and green emission’ (Nature, 421, 54(2003)), they disclose the combination of polymers to continuously emit light of red, green but blue colors by voltage-tuning; further, the paper of Y. Z. Wang, R. G. Sun, F. Meghdadi, G. Leising, and A. J. Epstein, ‘Multicolor multilayer light-emitting devices based on pyridine-containing conjugated polymers and para-sexiphenyl oligomer’ (Appl. Phys. Lett., 74, 3613(1999)) discloses small molecules in multilayer polymer which structure may be destroyed in high voltage operating range (about 20˜30V) and damaged at some components of device. U.S. Pat. No. 6,235,414 (Epstein, et al./May 22, 2001) discloses a color variable bipolar/AC light-emitting devices.

The difficulties of these disclosed techniques comprise at least applying conjugated polymers incompletely by spin-coating process and mixed with some steps of heat transfer or heat evaporation, which is more complicated than simple whole spin-coating process; controlling the device by voltage with switching between red and green emission but not continuously covering the whole visible spectrum range.

### SUMMARY OF THE INVENTION

The major object of this invention is to provide a LEDs structure which can emit light with a wide range of color, continuously turned by the applied voltage. A second object of this invention is to provide a process for manufacturing above mentioned structure applying conjugated polymers only by spin-coating process.

In addition, the structure of LEDs device is suitable for manufacturing larger area display or special luminance and signals.

The structure of this invention is typically shown in FIG. 1(a), which comprises a transparent electrode (TE) or a hole injection layer (HIL), several organic layers and an uppermost electron injection layer (EIL), characterized in choosing material of conjugated polymers with proper electron affinity (EA) and ionization potential (IP) for the organic layers. The device further comprises a hole transfer layer (HTL) between the hole injection layer (HIL) and a first organic layer; Further, the device comprises an electron barrier layer (EBL) between the hole transfer layer (HTL) and the first organic layer.

Wherein the organic polymer for red emission is selected from MEH-PPV, PFR; the organic polymer for green emission is selected from DP10-PPV, BEHF; the organic polymer for blue emission is selected from PFO, BEHF, BP79.

Wherein the transparent electrode (TE) or the hole injection layer (HIL) is ITO or IZO; the hole transfer layer (HTL) is PEDOT; the electron barrier layer (EBL) is PVK; the electron injection layer (EIL) is selected from metals of low power function such as Ca/Al, or insulator with low thickness, such as LiF.

Color-tuning can be realized in a structure of multilayer LED if the electron-hole recombination zone is controlled by the voltage. Due to the presence of the electron traps in the most conjugated polymers including PPV and PF, the electron mobility μₑ is much smaller than the hole mobility μₕ. So the holes can easily move away from the anode while the electrons hardly move far away from the cathode. The carrier mobility depends on the electron field E in the Poole-Frenkel form: μ=μ₀exp(γ√E). The parameter γ determines how rapidly the mobility increase with E. As the voltage bias increases, the electron traps are gradually filled by the injected current and μₑ increases strongly.

This corresponds effectively to a larger γ for μₑ than for μₕ. For the typical case of poly [2-methoxy-5(2′ethyl-hexyloxy)-1,4-phenylene vinylene](MEH-PPV), it is shown that μₕ=37μₑ at zero field, while μₕ=2.2μₑ at E=2×10⁸ V/m. Light emission is due to the recombination of the holes and electrons. At low bias, the electron distribution concentrates near the cathode, while the hole distribution is more extended from the anode due to the higher mobility. So most of the recombination takes place near the cathode. As the bias increases, the electron distribution becomes more extended, and the recombination moves from the cathode toward the anode. In the single-layer LED, such motion of recombination zone does not alter the emission of color. However, the color does vary due to such zone motion in multilayer LED whose layers emit with different colors. At low bias, recombination occurs only in the layer nearest to the cathode. As bias increases, electron becomes able to move out of the nearest layer and recombination takes place in the other layers successively. An electron blocking layer is needed to enhance the electron density and recombination in the farthest layer from the cathode at high bias by confining the electron near the interface with the blocking layer. It is expected that in such multilayer LEDs the motion of recombination zone through different layers caused a continuous change in the weighting of the emission from each layers. The overall color can therefore be controlled by the voltage.

The formation of the excitons is proportional to the product of the concentration for hole and electron. Hence, the luminescence region is gradually pushed away from the cathode as the voltage is increased.

Based on the upper characteristics, choosing material with proper electron affinity (EA) and ionization potential (IP), utilizing the ease film formation for polymer by spin-coat, the full color light emitting diode can be fabricated with the structure of bipolar-junction transistor, luminescent polymers of red, green and blue light, which can modulate luminescence color and light intensity independently.

### BRIEF DESCRIPTION OF DRAWINGS

In the text which follows, the invention is described by way of example on the basis of the following exemplary embodiments:

FIG. 1, (a) shows the structure of this invention, which typically comprises a ITO glass, a PEDOT film, several organic layers and an uppermost Ca/Al film; (b) shows the material for each layers together with energy gap according to FIG. 1(a); (c) shows the results of computer simulation as CIE coordinate chart for the structure of FIG. 1(b).

FIG. 2, (a) shows the structure for Device A, namely a multi-layer LED□(b) and (c) show the normalized emission spectrum and picture of Device A with triple emission layers.

FIG. 3, (a) shows the device structure for Device B together with the electron affinity (EA) and ionization potential (IP); (b) shows the current and luminance as functions of voltage; (c) shows the results of computer simulation as CIE coordinate chart for the structure of FIG. 3(a).

FIG. 4, (a) and (b) show the structure for Device C together with normalized spectrum of a double-layer device C (GB); (c) shows the current and luminance as functions of voltage; (d) shows the results of computer simulation as CIE coordinate chart for the structure of FIG. 4(a).

### DETAILED DESCRIPTION OF THE INVENTION

There are two key issues for the invention:
1. Choosing proper material: At the first, the material for each layer must be able to be resolved into organic solution then spin-coated to form film. Secondly, the intrinsic semiconductor must be able to be made as very smooth thin film (20˜30 nm). Then, the electron affinity and ionization potential between each layer should align properly to lowering the energy barrier as the electron and hole crossing the interface between each layer. Moreover, it is better for the luminescence layer to use more efficient and commercialized material. Finally, the electron affinity for electron-block layer should be much higher than the electron affinity for blue-light layer in order to block electrons more efficiently and let blue light being more intensive as higher voltage being exerted.
2. Interface solubility problem between heterolayers: The most important characteristic for the invention is using spin-coat to form film for each layer, up to six. It should be paid much attention for the solution of each layer to avoid unexpected destruction as spin-coating each layer.

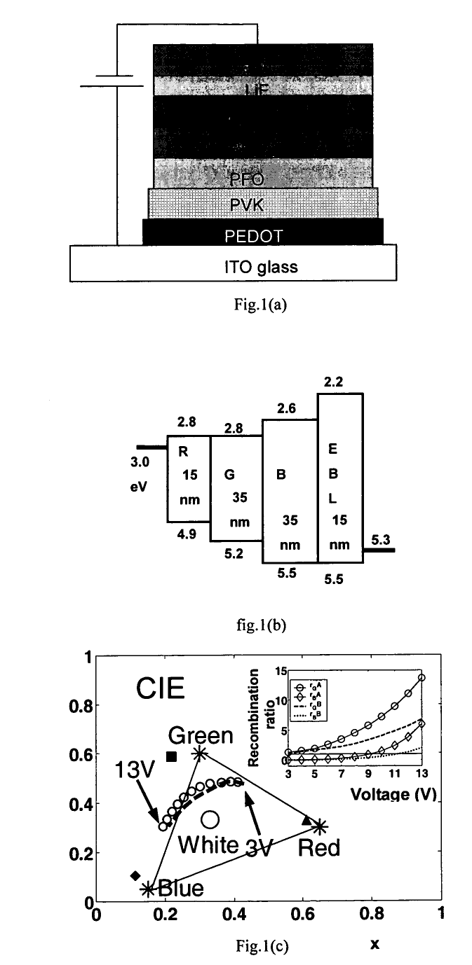

The structure of the device according to present invention is shown in FIG. 1(a), and the material for each layers together with energy gap is shown in FIG. 1(b), that is, a device with structure has various recombination of red (R), green (G), and blue (B) layers. FIG. 1(c) shows the results of computer simulation for the structure of FIG. 1(b), it is found that the color-tuning of emission varies from point (0.40, 0.49)(orange), through point (0.30, 0.50)(green), and finally to point (0.20, 0.30)(blue) in CIE coordinate chart while the voltage increases from 3V to 13V.

In order to concretely describe the details of structure, materials of each layer and the results of a computer simulation are presented as follows.

### PREFERRED EMBODIMENTS

Following devices are designed to achieve red/green/blue emission, red/green emission and green/blue emission by applying different material of layers.

1. Device A

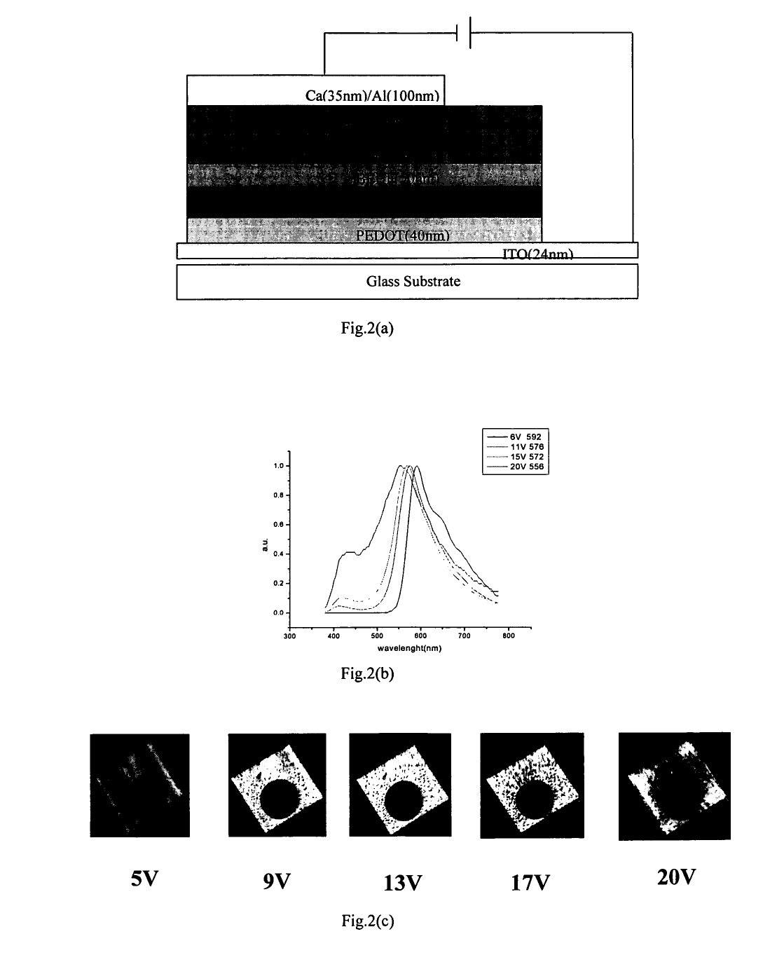

Device A which is a four multilayered LEDs is obtained with various recombination of red (R), green (G), and blue (B) layers. The device structure for Device A is shown in FIG. 2(a). There has been used MEH-PPV for R, poly (2,3-diphenylphenylene vinylene) (DP10-PPF) for G 1, Dow Chemical LUMATION Green-B polyfluorene (DPF) for G 2, and poly[9,9-di-(2-ethylhexy)-fluorenyl-2,7-diyl] (BEHF) for B. MEN-PPV and DP10-PPF are synthesized, DPF is from Dow Chemical Company, and BEHF is from Aldrich.

The peaks of photoluminescence (PL) for the polymers are 592 nm (R), 500 nm (G1), 540 nm (G2), and 424 nm (B). Poly(3,4-ethylenedioxythiophene) doped with polystyrene sulphonated acid (PEDOT:PSS) is used as the hole transport layer. A layer of poly(N-vinyl carazole) (PVK) is added between PEDOT:PSS and the emissive layer in order to block the electrons.

All the emissive polymers are dissolved in toluene with weight percentages 0.3 wt. □ for R, 0.5 wt. □ for G1, 1.2 wt. □ for G2, and 1.5 wt. □ for B. The concentration for R and G is lower than what is normally used for LED in order to have a thinner film. Each layer thickness for Devices A is: (B/G1/R):PEDOT/PVK (50 nm)/BEHF (70 nm)/DP10-PPV (20 nm)/MEH-PPV (20 nm)/Ca. Each polymer layer is baked at 1200 for 60 minutes in vacuum (10⁻³ torr) after spin-coating. It is crucial that the spin coating of the subsequent layer does not dissolve the previous layer. To check this, pure toluene is spin-cast on baked film and it is found that the film thickness is reduced by no more than 5□. The Ca/Al cathode is evaporated and packaged in a glove box.

The normalized emission spectrum and picture of Device A with triple emission layers is shown in FIG. 2(b), 2(c). At 6 V, the spectrum is identical to the PL of MEH-PPV because the electron-hole recombination concentrates near the cathode. As the bias voltage increases, there is a significant blueshift. It is yellow at 9V and green at 13 V. The emission becomes greenish blue after 17 V. In the spectrum one sees clearly the emergence of the peak around 424 nm due to BEHF. The spectrum is, however, never dominated by the blue emission up to 20 V. The main reason is that the efficiency of blue polymer is much weaker than red and green polymers. Better color-tuning at highly voltage could be realized if more efficient blue polymers (or less efficient red and green) are used. The highest brightness decreases and the current saturates at the same time. This peculiar saturation behavior is reproduced in many triple-layer devices with similar structures. One possible reason is that as the voltage increase, a large amount of electrons are accumulated at the barrier between R and G, which screen the electric field efficiency in the very thin R layer and cause an effective increase in the injection barrier from the cathode to R.

2. Device B

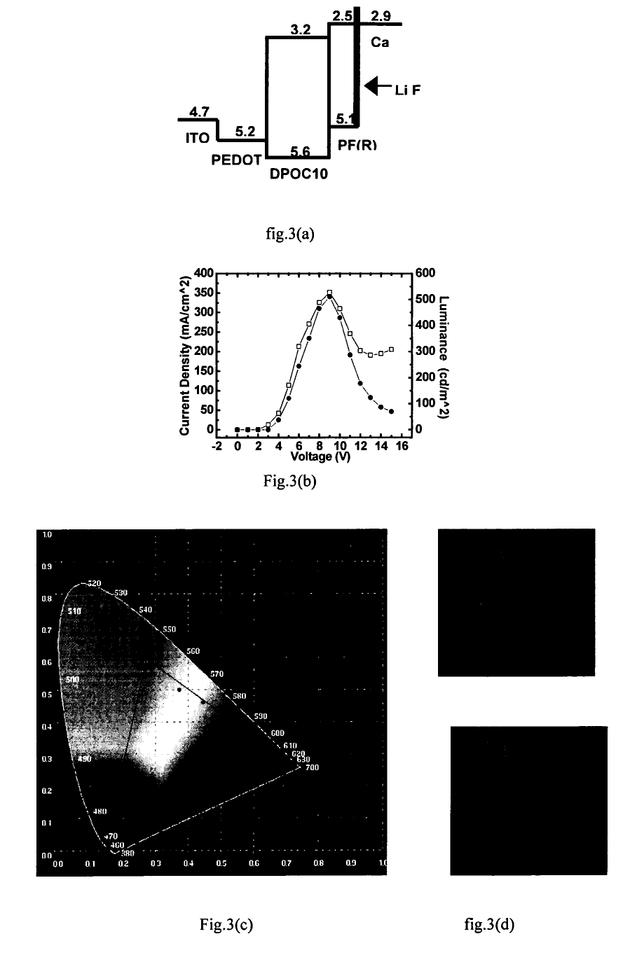

A two multilayered LEDs as Device B is obtained with recombination of red (R) and green (G) layers, wherein the material PF is for red and DPOC10 for green. The device structure for Device B together with the electron affinity (EA) and ionization potential (IP) are indicated in FIG. 3(a). The starting spectrum is 624 nm for voltage as low as 4V; when voltage increases to 9V, 13V, simultaneously the peak of spectrum decreases to 620 nm, 500 nm, which is in the spectrum range of green. The current and luminance are plotted in FIG. 3(b) as functions of voltage. In general, the double-layer devices are much brighter than the triple-layer devices.

According to CIE coordinate chart in FIG. 3(c), (d), the color-tuning of emission varies from point (0.50, 0.43)(red) to point (0.38, 0.5)(green).

3. Device C

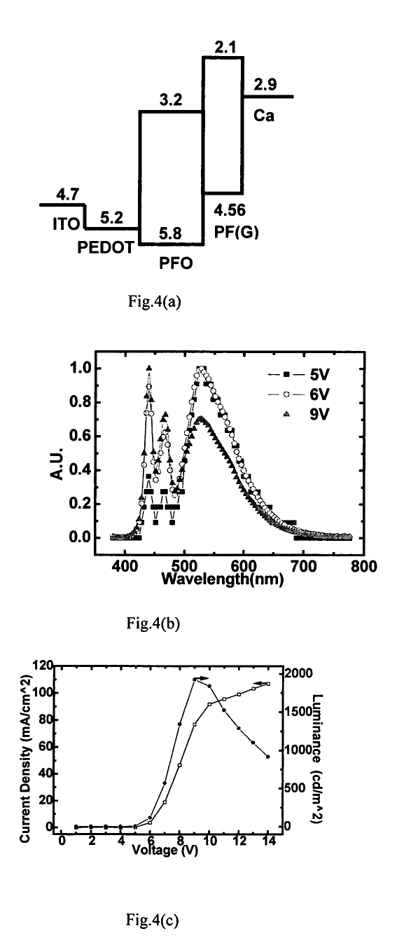

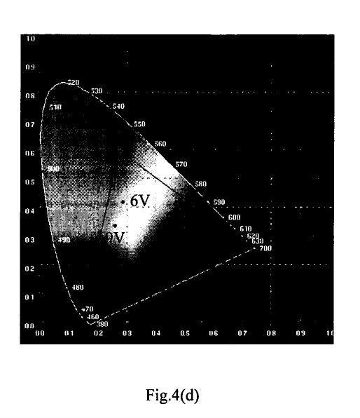

A two multilayered LEDs as Device C is obtained with recombination of green (G) and blue (B) layers, wherein the material PF is for green and PFO for blue. The device structure for Device C together with normalized spectrum of a double-layer device C (GB) are indicated in FIG. 4(a), 4(b). The starting spectrum is 528 nm for voltage as low as 6V; when voltage increases to 9V, simultaneously the peak of spectrum decreases to 440 nm, which is in the spectrum range of blue. The current and luminance are plotted in FIG. 4(c) as functions of voltage. In general, the double-layer devices are also much brighter than the triple-layer devices.

According to CIE coordinate chart in FIG. 4(d), the color-tuning of emission varies from point (0.29, 0.41)(green) to point (0.26, 0.34)(blue).

The invention has been described with reference to its preferred embodiments. Those of ordinary skill in the art may, upon reading this disclosure, appreciate changes or modifications which do not depart from the scope and spirit of the invention as described above or claimed hereafter.

We claim that:

1. An electrical illumination device which comprises a transparent electrode (TE) or a hole injection layer (HIL), several organic layers and an uppermost electron injection layer (EIL), characterized in choosing material of conjugated polymers with proper electron affinity (EA) and ionization potential (IP) for the organic layers.

2. The device according to claim 1, further comprising a hole transfer layer (HTL) between the hole injection layer (HIL) and a first organic layer.

3. The device according to claim 2, further comprising an electron barrier layer (EBL) between the hole transfer layer (HTL) and the first organic layer.

4. The device according to claim 1, wherein the organic polymer for red emission is selected from MEH-PPV, PFR.

5. The device according to claim 1, wherein the organic polymer for green emission is selected from DP10-PPV, BEHF.

6. The device according to claim 1, wherein the organic polymer for blue emission is selected from PFO, BEHF, BP79.

7. The device according to claim 1, wherein the transparent electrode (TE) or the hole injection layer (HIL) is ITO or IZO.

8. The device according to claim 1, wherein the hole transfer layer (HTL) is PEDOT.

9. The device according to claim 1, wherein the electron barrier layer (EBL) is PVK.

10. The device according to claim 1, wherein the electron injection layer (EIL) is selected from metals of low power function, or insulator with low thickness.

11. The device according to claim 10, wherein the metals of low power function are Ca/Al.

12. The device according to claim 10, wherein the insulator with low thickness is LiF.

13. A process of color-tuning for electrical illumination device, which provides wide-range low-voltage continuous color due to the position of the electron-hole recombination as the voltage varies.

14. The process according to claim 13, wherein the color is determined by the field and the luminance is determined by the current separately.

15. A process for fabricating the device according to claim 1, wherein the organic layers can be easily formed, utilizing the ease film formation for polymer by spin-coat, the full color light emitting diode can be fabricated with the structure of bipolar-junction transistor, luminescent polymers of red, green and blue light, which can modulate luminescence color and light intensity.
